(19) United States
(12) Patent Application Publication
(10) Pub. No.: US 2015/0243864 A1
(43) Pub. Date: Aug. 27, 2015

(54) Method for Manufacturing Optical Device and Optical Device Manufactured by Same

(71) Applicant: Point Engineering Co., Ltd., Asan-si, Chungcheongnam-do (KR)

(72) Inventors: Bum Mo Ahn, Suwon-si (KR); Ki Myung Nam, Cheonan-si (KR); Young Chul Jun, Ansan-si (KR)

(21) Appl. No.: 14/418,966

(22) PCT Filed: Aug. 1, 2013
(86) PCT No.: PCT/KR2013/006957

§ 371 Date: Feb. 2, 2015

(30) Foreign Application Priority Data
Aug. 3, 2012 (KR) 10-2012-0085192
Nov. 19, 2012 (KR) 10-2012-0130777

(51) Int. Cl. H01L 33/64; H01L 33/00; H01L 33/44; H01L 33/62

(52) U.S. Cl. CPC H01L 33/644; H01L 33/62; H01L 33/0095; H01L 33/44; H01L 2933/0075; H01L 2933/0033; H01L 2933/0025; H01L 2933/0066

(57) ABSTRACT

The present invention relates to a method for manufacturing an optical device and to an optical device manufactured by the method, in which heat-dissipating performance by a heat sink and thermal insulation performance between a substrate and the heat sink are improved and workability is enhanced. According to a first characteristic of the present invention, the method for manufacturing an optical device comprises: (a) a step of preparing a disk for an optical device having a vertical thermal insulation layer; (b) a step of forming a groove along a cut line formed on the lower surface of the disk for an optical device; (c) a step of applying liquid insulation material to the surface on which the groove is formed and hardening the liquid insulation material to form an electrically insulating layer having a planar surface; and (d) a step of forming a fixing hole penetrating in a vertical direction through both the disk for an optical device and the groove.

### TECHNICAL FIELD

The present invention relates to a method for manufacturing an optical device and to an optical device manufactured thereby, more particularly, to a method for manufacturing an optical device which enhances the heat dissipation performance through the heat sink, and enhances the insulation performance between the substrate and the heat sink, and improves the workability, and an optical device manufactured thereby.

### BACKGROUND ART

Generally, semiconductor light emitting diode (LED) receives attention from various fields as an environment friendly light source. Recently, as applications of LEDs are expanding to various fields such as interior and exterior illuminations, automobile headlights, and back-light units (BLU) of display devices, there are needs for high optical efficiency and excellent heat radiation characteristics. For high efficiency LEDs, materials or structures of the LEDs should be improved primarily, however there is a need for improvement in the structures of the LED packages and the materials used therein.

In such high efficiency LEDs, high temperature heat is produced, therefore this heat must be radiated effectively otherwise temperature rising on the LEDs causes ageing of the characteristics thereby shortening the lifetime. In high efficiency LED packages, efforts on effective radiation of the heat produced by the LEDs are making progress.

Hereinafter, various kinds of devices including the LEDs which emit light will be referred to as ‘optical elements,’ and various products which include more than one optical element will be referred to as ‘optical device.’

FIGS. 1A and 1B are the plane views for explaining the manufacturing processes for the optical devices of different structures which are made from the different base substrates for manufacturing optical devices. As shown in FIG. 1A, in manufacturing an optical device of the prior art, in order to enhance workability, first, after forming a cavity (C), which comprises a groove having a predetermined depth and a downwardly narrowing taper starting from the upper surface of the base substrate (A) containing multiple vertical insulation layers (B) and accommodates a vertical insulation layer (B), on each of the base substrates (A), then the wire (E) is bonded with the optical element (D) being disposed inside each cavity (C). Later, manufacturing of the unit optical device is completed by cutting the base substrate (A) horizontally and vertically along the cutting line (CL). Later, these diced optical devices are individually bonded to the corresponding heat sinks for rapid heat dissipation.

A total of 6 optical devices, wherein 3 optical elements and 2 optical elements are disposed in horizontal direction and in vertical direction respectively, are manufactured from the base substrate (A) for optical devices in FIG. 1A. In each optical device, the horizontally arranged optical elements are serially connected to each other, while the vertically arranged optical elements are connected to each other in parallel.

Next, in the example of FIG. 1B, a total of 6 optical devices are manufactured from the single base substrate (A′) for optical devices, wherein 3 optical elements and 2 optical elements are disposed in the horizontal direction and in the vertical direction respectively per one optical device. However, unlike the example of FIG. 1A, it has a structure, wherein all (total of 6) the optical elements (D) are disposed inside of a single cavity (C′), and the bonding wire (E) which serially connects the neighboring optical elements (D) is directly bonded to the electrode of the optical elements (D) without intermediating the substrate.

The foregoing structure is only an example, optical devices having various structures may be manufactured from the base substrates having various sizes or structures.

FIG. 2 is a cross-sectional view for describing a method for connecting a unit optical device, which is manufactured according to FIG. 1A of the prior art, to the heat sink. As illustrated in FIG. 2, a substrate 30 is bonded to the heat sink 20 comprising an aluminum material and the like in order to dissipate the heat generated from the optical device 40. As a material for bonding the substrate 30 and the heat sink 20, a thermal interfacial material (TIM) layer 10 having excellent heat transfer characteristic, such as a silicon oil and the like which is filled with aluminum oxide, zinc oxide, or boron nitride and the like, are mostly used. Furthermore, an insulation layer 22 is formed by anodizing the upper surface of the heat sink 20 for electrically insulating between the substrate 30 and the heat sink 20.

However, according to the foregoing optical device of the prior art, since there is limitation in reducing the thickness of the adhesive TIM layer 10, there is a problem in that the heat dissipation characteristics are degraded due to the thickness thereof even though a material having an excellent heat transfer rate is used. Moreover, since the process of aligning the optical device precisely on the heat sink is manually performed, the productivity is decreased, and there is a problem in that a uniform heat dissipation performance may not be assured due to the difference in the overall deposition thickness or the partial thickness difference of the adhesive TIM layer depending on the workmanship of the worker.

In addition, since the process of forming an electrical insulation layer through the anodizing of the upper surface of the heat sink 20 is required for electrical insulation, there is a problem in that processes are increased.

Most of all, for each individual unit optical device manufactured from the base substrate (A) for the optical devices as illustrated in FIG. 1A of the prior art, for example, for the optical device separated from the far right end in FIG. 1A, burrs are generated at the far left end during the separation process such as sawing or dicing as illustrated in FIG. 2, and may damage the anodized insulation layer 22 which is a very thin layer formed on the upper surface of the heat sink 20, thereby causing a failure problem such as a short due to the insulation breakdown between the substrate 30 and the heat sink 20.

### SUMMARY OF INVENTION

### Technical Problem

An objective of the present invention, devised to solve above described problems, is to provide a method for manufacturing an optical device which enhances the heat dissipation performance through the heat sink, and enhances the insulation performance between the substrate and the heat sink, and improves the workability, and an optical device manufactured thereby.

### Solution to Problem

According to a first aspect of the present invention, there is provided a method for manufacturing an optical device including: (a) preparing a base substrate for optical device having a vertical insulation layer; (b) forming a groove along a cutting line in a bottom surface of the base substrate; (c) forming an insulation layer having a flat surface by applying and curing a liquid insulation material on a surface where the groove is formed; and (d) forming a fixing hole vertically penetrating both the base substrate and the groove.

In the above described process configuration, a cavity having a groove having a predetermined depth starting from an upper surface of the base substrate and accommodating the vertical insulation layer is formed after the step (c) and before, simultaneously with or after the step (d).

The method further includes: (e) bonding a wire after an optical element is mounted on an upper surface of the base substrate.

The method further includes: (f) separating the optical device manufactured through the step (e) along the cutting line.

The method further includes: (e-1) bonding a wire after the optical element is disposed in the cavity of the base substrate.

The method further includes: (f-1) separating the optical device manufactured through the step (e-1) along the cutting line.

According to a second aspect of the present invention, there is provided a method for manufacturing an optical device including: (h) preparing a base substrate for optical device having a vertical insulation layer; (i) forming a groove on a bottom surface of the base substrate along a cutting line; (j) forming an electrical insulation layer having a flat surface by curing a liquid insulation material applied over a surface where the groove is formed; and (k) forming an intermediate soldering layer on the electrical insulation layer.

In the above described process configuration, the step (k) includes: (k-1) forming a seed layer using a sputtering process or an activation treatment process for palladium (Pd) on the electrical insulation layer; and (k-2) forming a plating layer using an electroplating process or an electroless plating process on the seed layer.

The step (k-1) is performed in a state where a masking layer is formed on an upper surface of the base substrates, and the step (k-2) is performed after a cavity having a groove having a predetermined depth starting from the upper surface of the base substrate and accommodating the vertical insulation layer is formed after the step (k-1).

The method further includes: (1) wire-bonding an optical element after the optical element is mounted on an upper surface of the base substrate; and (m) separating the optical device along the cutting line.

The method further includes: (n) wire-bonding the optical element after the optical element is disposed in the cavity of the base substrate; and (o) separating the optical device along the cutting line.

### Advantageous Effects of Invention

According to a method for manufacturing an optical device and to an optical device manufactured thereby, the heat dissipating characteristics may be enhanced by bonding a heat dissipating epoxy layer, which can be formed to have a relatively thinner thickness than the adhesive TIM layer of the prior art, to the bottom surface of the substrate. Furthermore, it is effective in reducing the possibility of electrical short through enhancement of the electrical insulation since burrs are not generated during the cutting process of the substrate.

In addition, not only the bonding between the heat sink and the substrate can be easily performed by integrating the electrical insulation layer into the substrate, but also the uniform heat dissipating characteristics can be guaranteed independent of workmanship of the workers.

### BRIEF DESCRIPTION OF DRAWINGS

FIG. 1A and 1B are plane views for describing the manufacturing process for the optical devices having different structures from different base substrates for optical device.

FIG. 2 is a cross-sectional view describing a conventional method for bonding a unit optical device to a heat sink.

FIG. 3 is a flow diagram describing a method for manufacturing an optical device according to an exemplary embodiment of the present invention.

FIGS. 4A to 4E are the prospective views of the processes in the main steps of the method for manufacturing an optical device as illustrated in FIG. 2, and the cross-sectional views thereof taken along the line A-A.

FIG. 5 shows a perspective view of a single optical device manufactured according to the manufacturing method illustrated in FIG. 3, and the cross-sectional view thereof taken along the line A-A.

FIG. 6 is a cross-sectional view of the coupled state between the optical device illustrated in FIG. 5 and the heat sink.

FIG. 7 is a flow diagram for describing a method for manufacturing a substrate for optical device according to another exemplary embodiment of the present invention.

FIGS. 8A to 8G are the prospective views of the processes in the main steps of the manufacturing method as illustrated in FIG. 7, or the cross-sectional views thereof taken along the line A-A.

FIG. 9 is a perspective view of a base substrate for optical device manufactured according to the method described in FIG. 7.

FIG. 10 is a perspective view of an optical device separated along the cutting lines in FIG. 9.

FIG. 11 is a cross-sectional view of the coupled state between the optical device illustrated in FIG. 10 and the heat sink.

FIG. 12 is a flow diagram for describing a method for manufacturing a substrate for optical device according to another exemplary embodiment of the present invention.

FIGS. 13 and 14 are exemplary cross-sectional views illustrating the coupled state between the optical device having a horizontal insulation layer, and the heat sink according to another exemplary embodiment of the present invention.

FIG. 15 is an exemplary cross-sectional view illustrating the coupled state between the optical device having a horizontal insulation layer, and the heat sink according to another exemplary embodiment of the present invention.

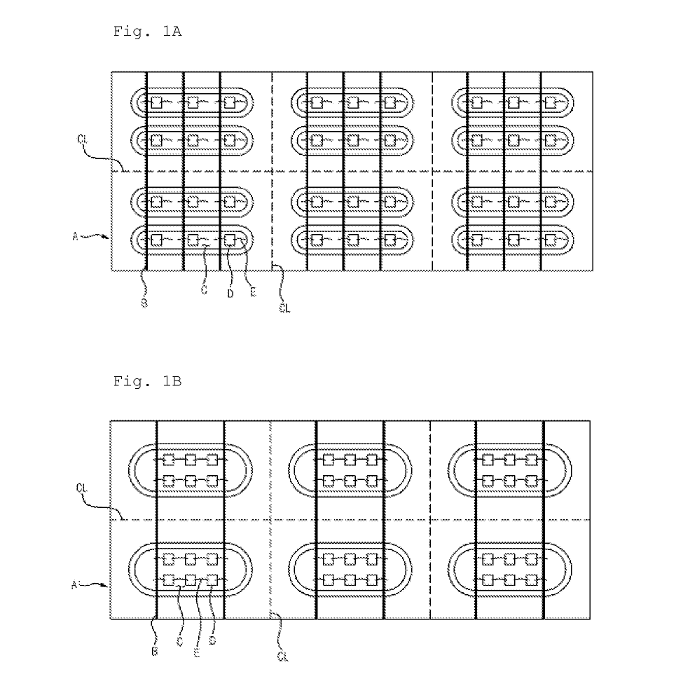

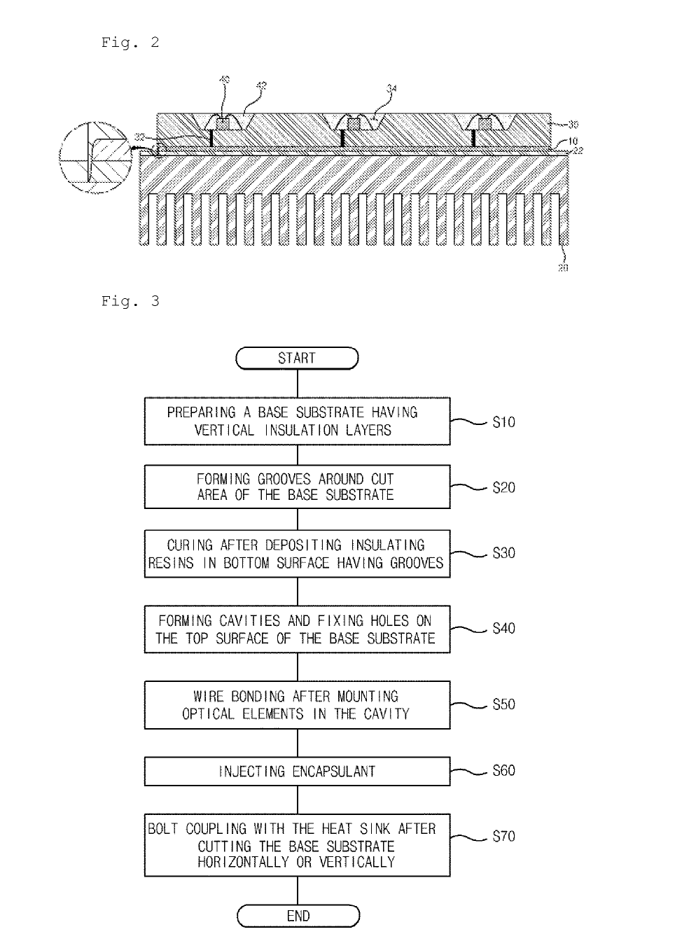

### DETAILED DESCRIPTION OF EMBODIMENT

Hereinafter, a preferred exemplary embodiment of a method for manufacturing an optical device, and an optical device manufactured thereby will be described in detail with reference to the accompanying drawings.

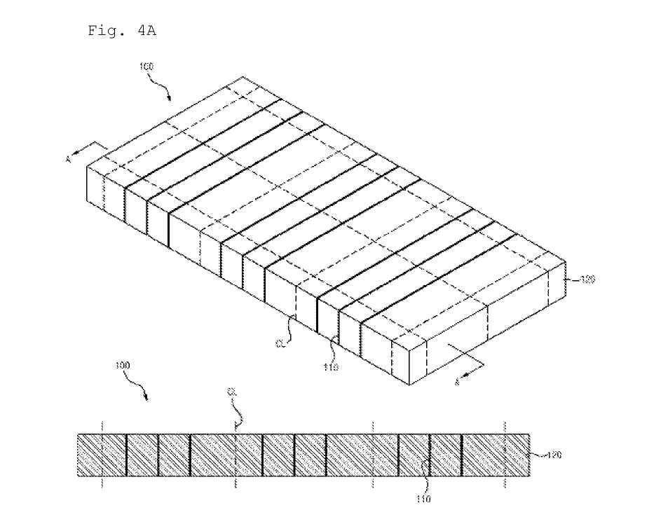

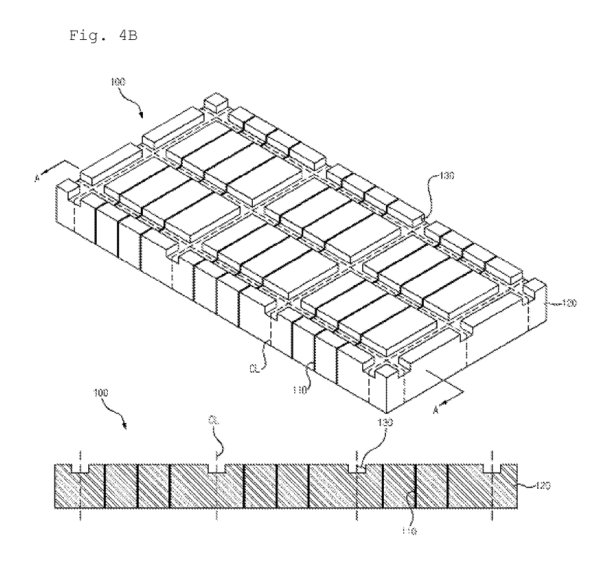

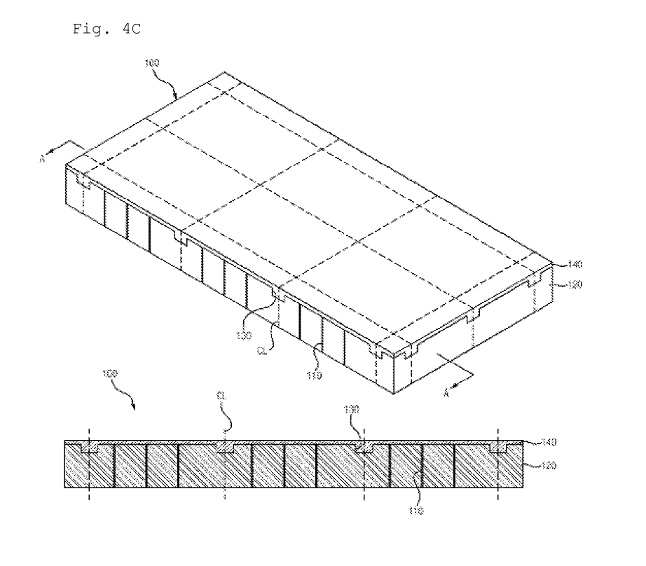

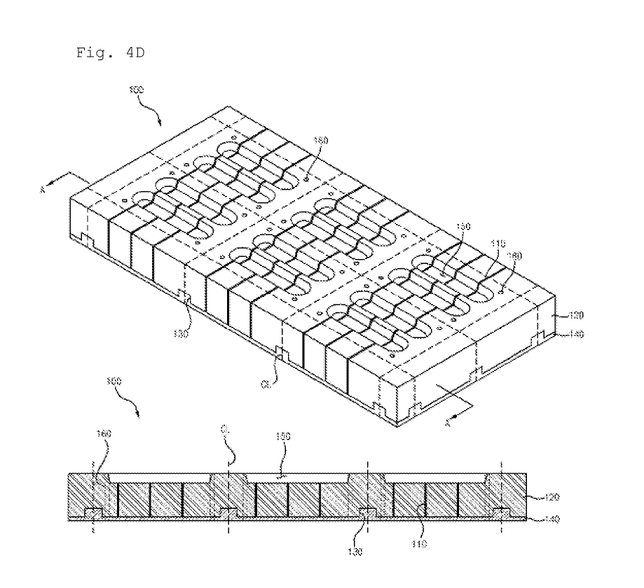

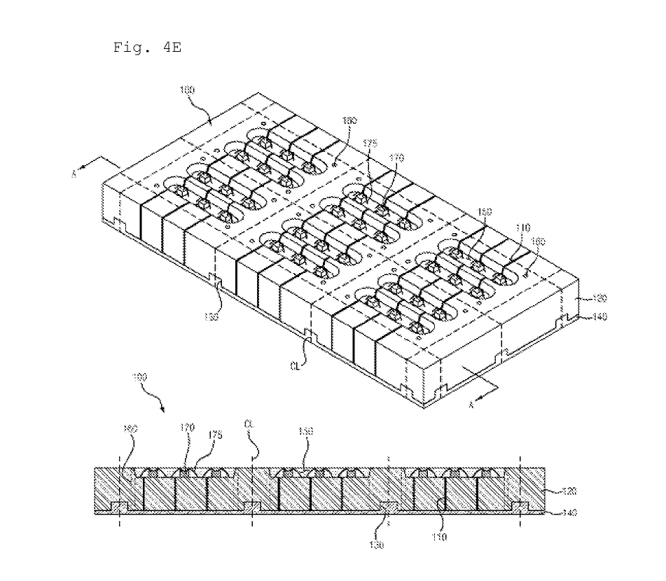

FIG. 3 is a flow diagram describing a method for manufacturing an optical device according to an exemplary embodiment of the present invention. FIGS. 4A to 4E are the prospective views of the processes in the main steps of the method for manufacturing an optical device as illustrated in FIG. 2, and the cross-sectional views thereof taken along the line A-A.

As illustrated in FIG. 3, according to a method for manufacturing an optical device according to an exemplary embodiment of the present invention, first, in step S10, a base substrate for optical device 100 (hereinafter referred to as ‘base substrate’) having at least one vertical insulation layer 110 is prepared as illustrated in FIG. 4A. In FIG. 4A and figures thereafter, 120 represents an optical device substrate, and CL represents a cutting line to be used in the processes hereinafter.

Next, in step S20, as illustrated in FIG. 4B, a groove 130 having a sufficiently larger width than that of the cutting line (CL) is formed around the cutting line of the bottom surface of the base substrate 100 that has been prepared in this way, and such a groove 130 may be formed by mechanical machining or chemical etching. The depth or the width of the groove 130 may be appropriately determined within the range that may sufficiently prevent the generation of burrs during the cutting without affecting the hardness of the base substrate 100. Such groove 130 may be formed crossing the bottom surface of the base substrate 100 horizontally or vertically depending on the overall size of the base substrate 100 or the number of optical devices to be arranged in the base substrate 100.

Next, in step S30, as illustrated in FIG. 4C, in the bottom surface of the base substrate 100 wherein the groove 130 is formed, the groove 130 is filled with a liquid heat dissipating epoxy until the overall surface is flattened thereby, then an electrical insulation layer 140 is formed by curing the liquid heat dissipating epoxy while heating. The material of such heat dissipating epoxy may be a thermo-plastic or a thermosetting epoxy resin, and the like. In the drawings hereinafter, the thickness of the electrical insulation layer 140 (including after-mentioned thicknesses of seed layer, plating layer, and soldering layer) is exaggeratedly illustrated with respect to the total thickness of the base substrate 100.

Next, in step S40, as illustrated in FIG. 4D, the base substrate 100 is flipped over such that the upper surface thereof, wherein the insulation layer 140 is not formed, is facing upwards. At this state, a cavity 150, which comprises a groove having a predetermined depth starting from the upper surface accommodating the vertical insulation layer 110, is formed to have a downwardly narrowing tapered shape. This type of cavity 150 may be formed by mechanical machining, chemical etching, and the like. Of course, optical elements may be directly mounted on the upper surface of the base substrate 100 without forming such cavity 150 depending on the types of the optical devices. Meanwhile, a plurality of fixing holes 160, which vertically penetrate both the base substrate 100 and the electrical insulation layer 140 are formed before or after or simultaneously with the machining the cavity 150. The locations or the number of the fixing holes 160 may be appropriately determined according to the number of the optical devices to be separated or the structure of the wire connection thereof.

Next, in step S50, as illustrated in FIG. 4E, wires 175 are bonded while the optical elements 170 are disposed in the corresponding cavities 150 respectively. In step S60, an encapsulant deposited with fluorescent substances for protecting the optical elements 170 and additionally for generating desired colors is injected into the cavity 150, and thereby the manufacturing of an optical device is completed.

Finally, in step S70, the base substrate is separated in either horizontally or vertically along the cutting line (CL) drawn in dotted lines, and used after bonding with the heat sink.

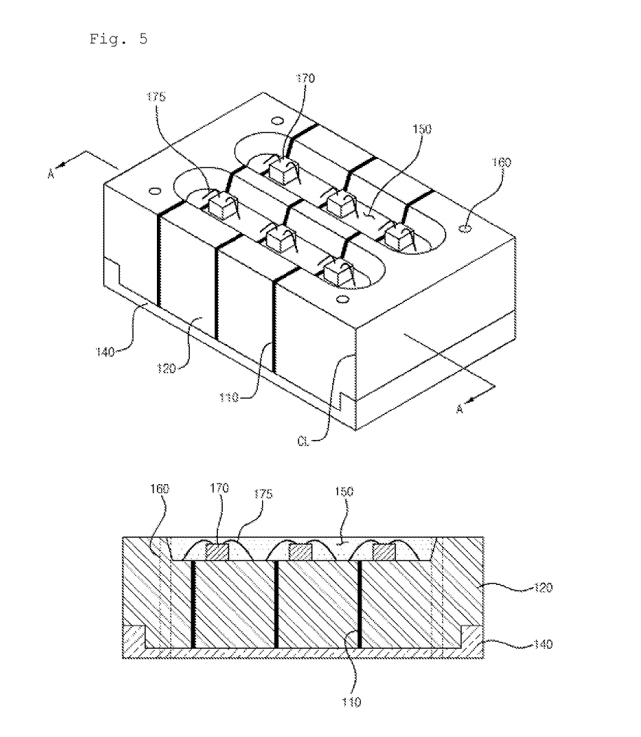

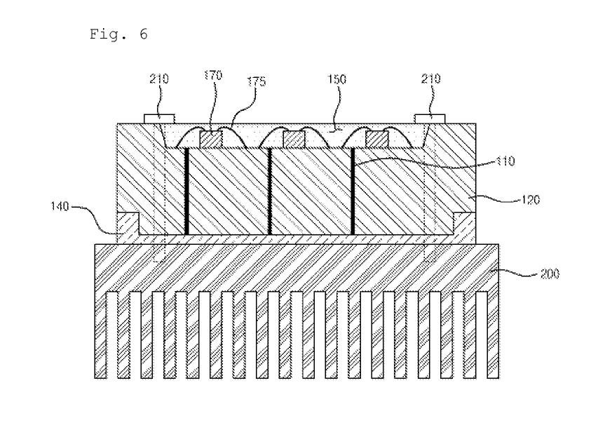

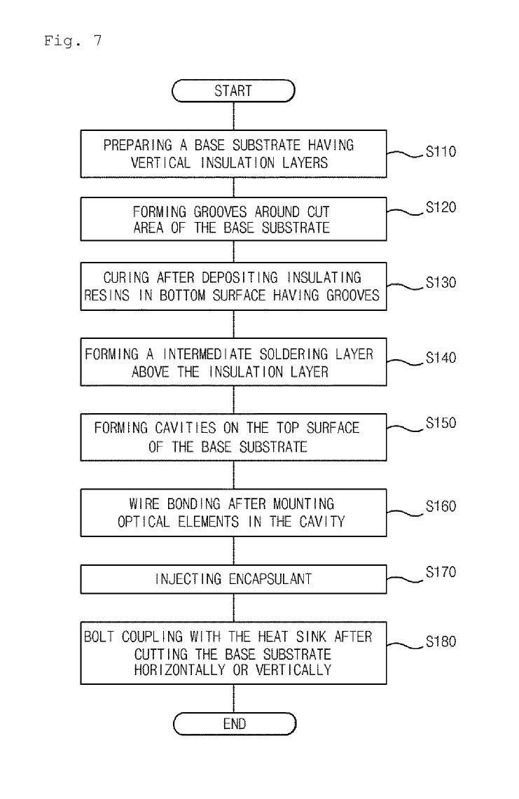

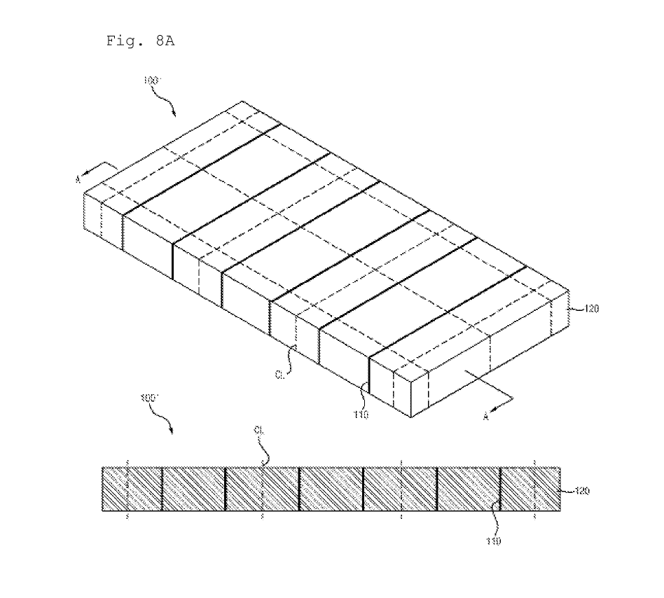

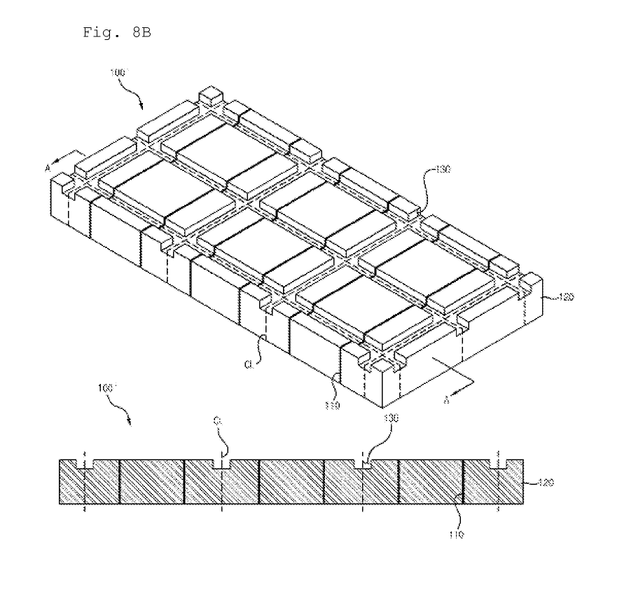

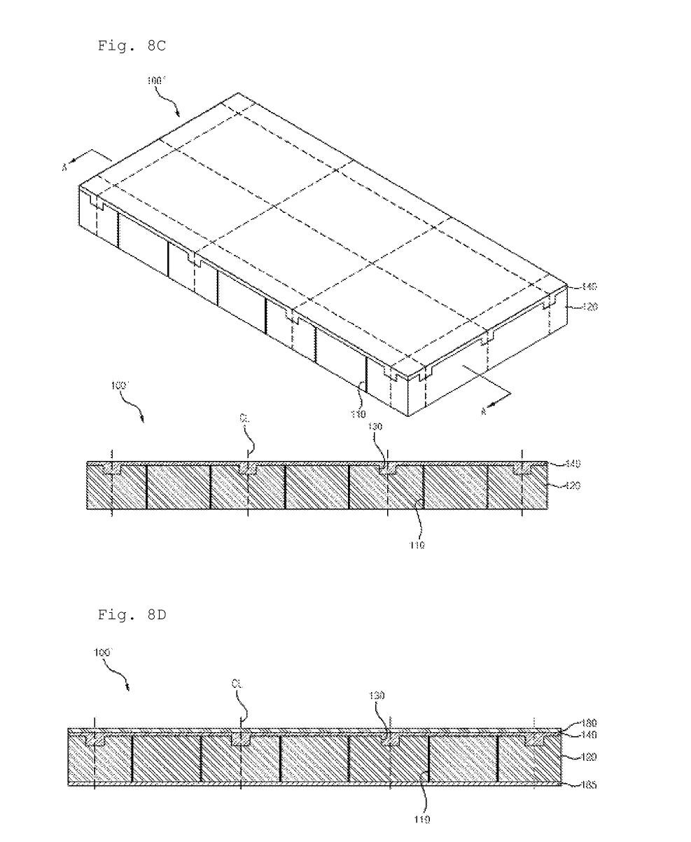

FIG. 5 shows a perspective view of a single optical device manufactured according to the manufacturing method illustrated in FIG. 3, and the cross-sectional view thereof taken along the line A-A. FIG. 6 is a cross-sectional view of the coupled state between the optical device illustrated in FIG. 5 and the heat sink. First, the optical device illustrated in FIG. 5, for example, may be the optical device located at the center top or center bottom with respect to the cutting line (CL) in the base substrate 100 for optical device illustrated in FIG. 4E. In the exemplary embodiment of the present invention, an optical device of a serial-parallel structure wherein 3 optical elements are horizontally connected (serial connection) and 2 optical elements are vertically connected (parallel connection) is shown. Total of 2 cavities 150 are provided for the horizontally arranged optical elements since they are disposed inside of the cavities 150 respectively. For the optical device illustrated in FIG. 5, the far left row and the far right row may function as a positive electrode or a negative electrode respectively.

According to an exemplary embodiment in FIG. 5, both the far left end and the far right end of the substrate become cut surfaces. Since the groove 130 is located at the bottom of the cut surfaces, generation of burrs are suppressed due to the relatively thick electrical insulation layer 140 which fills such groove 130. Thus, as illustrated in FIG. 6, a reliable electrical insulation between the heat sink 200 and the substrate may be guaranteed even when a bolt 210 is coupled with the heat sink 200 through the fixing hole 160. Of course, as illustrated in FIG. 6, when the related substrate is functioning as an electrode, a connecting member having an electrical insulating property, for example, a bolt 210 made of a synthetic resin material may be used. For reference, due to the cost increase and the durability degradation a metal bolt may be adopted instead of adopting a bolt 210 made of an insulating material. When a metal bolt is adopted, an electrical short caused by the metal bolt when coupled with the heat sink 200 may be prevented by forming a fixing hole 160 in the area of the substrate which is not functioning as an electrode.

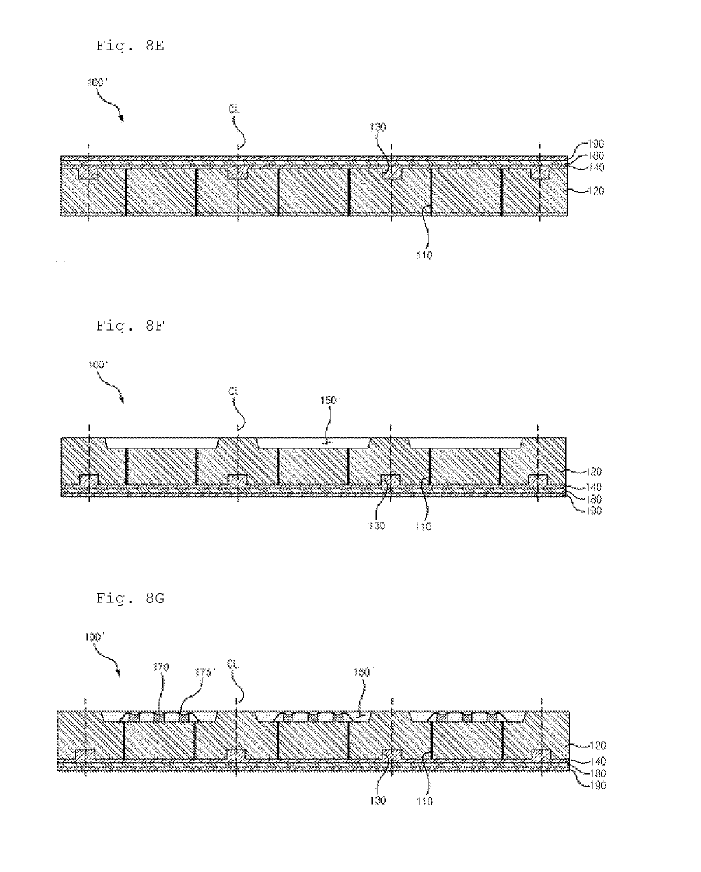

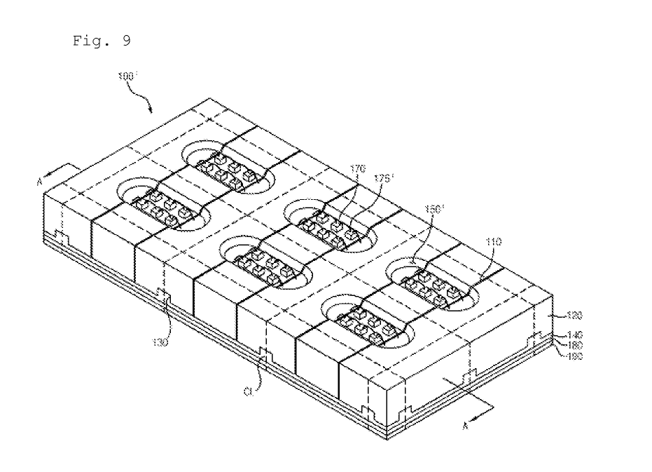

FIG. 7 is a flow diagram for describing a method for manufacturing a substrate for optical device according to another exemplary embodiment of the present invention. FIGS. 8A to 8G are the prospective views of the processes in the main steps of the manufacturing method as illustrated in FIG. 7, or the cross-sectional views thereof taken along the line A-A.

As illustrated in FIG. 7, according to a method for manufacturing an optical device according to another exemplary embodiment of the present invention, first, in step S110, a substrate for optical device 100′ having more than one vertical insulation layer 110 is prepared as illustrated in FIG. 8A.

Next, in step S120, as illustrated in FIG. 8B, a groove 130 having a sufficiently larger width than that of the cutting line (CL) is formed around the cutting line of the bottom surface of the base substrate 100′ that has been prepared in this way, and such a groove 130 may be formed by mechanical machining or chemical etching. The depth or the width of the groove 130 may be appropriately determined within the range that may sufficiently prevent the generation of burrs during the cutting without affecting the hardness of the base substrate 100′. Such groove 130 may be formed crossing the bottom surface of the base substrate 100′ horizontally or vertically depending on the overall size of the base substrate 100′ or the number of optical device to be arranged in the base substrate 100′.

Next, in step S130, as illustrated in FIG. 8C, in the bottom surface of the base substrate 100 wherein the groove 130 is formed, the groove 130 is filled with a liquid heat dissipating epoxy until the overall surface is flattened thereby, then an electrical insulation layer 140 is formed by curing the liquid heat dissipating epoxy while heating. The material of such heat dissipating epoxy may be a thermo-plastic or a thermosetting epoxy resin, and the like.

Next, in step S140, an intermediate soldering layer for guaranteeing the soldering between the heat sink typically made from aluminum on the electrical insulation layer 140 is formed. For this process, first, as illustrated in FIG. 8D, a seed layer 180 is formed above the electrical insulation layer 140. Such seed layer 180 may be made of copper, chrome, nickel, or palladium or an alloy made from more than any two of these elements. The seed layer 180 may be formed by using a sputtering process or an activation treatment process for palladium, and it is preferred that the upper surface of the base substrate 100′ is masked in order not to form a seed layer 180 on the upper surface of the base plate 100′. Reference numeral 185 in the drawing represents such mask layer. After forming a seed layer 180 in this way, a plating layer 190 is formed over the seed layer 180 as illustrated in FIG. 8E. Such plating layer 190 may be formed by electroplating or electroless plating silver (Ag) and the like. After forming a plating layer 190 in this way, the mask layer 185 is removed.

Next, in step S150, as illustrated in FIG. 8F, the base substrate 100′ is flipped over such that the upper surface thereof, wherein the intermediate soldering layer i.e. the plating layer 190 is not formed, is facing upwards. At this state, a cavity 150′, which comprises a groove having a predetermined depth starting from the upper surface accommodating the vertical insulation layer 110, is formed to have a downwardly narrowing tapered shape. This type of cavity 150′ may be formed by mechanical machining, chemical etching, and the like. Of course, optical elements may be directly mounted on the upper surface of the base substrate 100 without forming such cavity 150′ depending on the types of the optical devices.

Next, in step S160, as illustrated in FIG. 8G, wires 175′ are bonded while the optical elements 170 are disposed in the corresponding cavities 150′ respectively. In step S170, an encapsulant deposited with fluorescent substances for protecting the optical elements 170 and additionally for generating desired colors is injected into the cavity 150′, and thereby the manufacturing of an optical device is completed.

Finally, in step S180, the base substrate is separated in either horizontally or vertically along the cutting line (CL) drawn in dotted lines, and used after bonding with the heat sink.

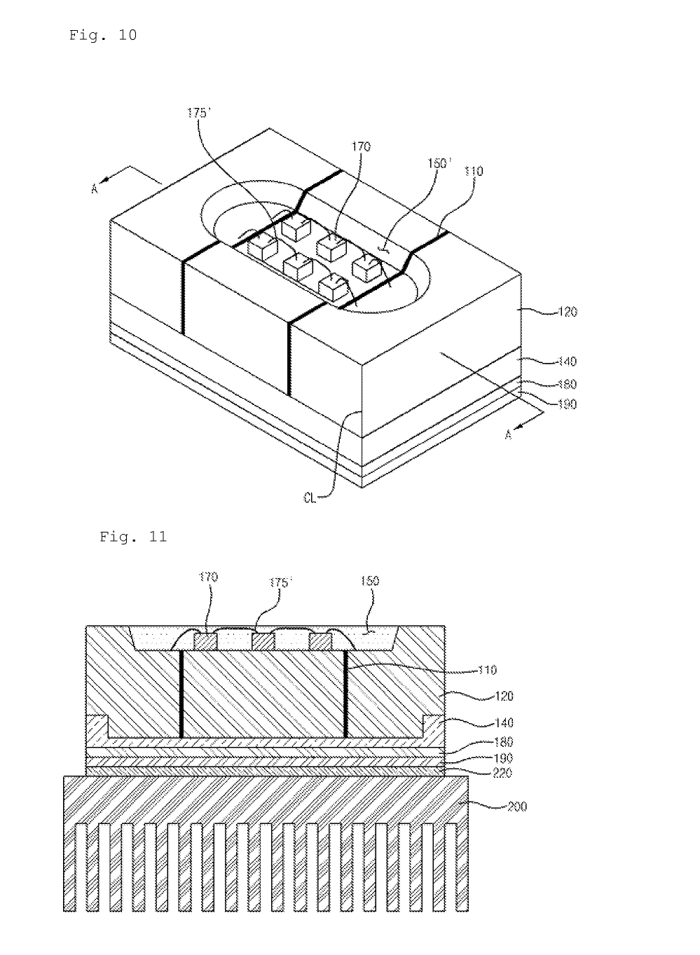

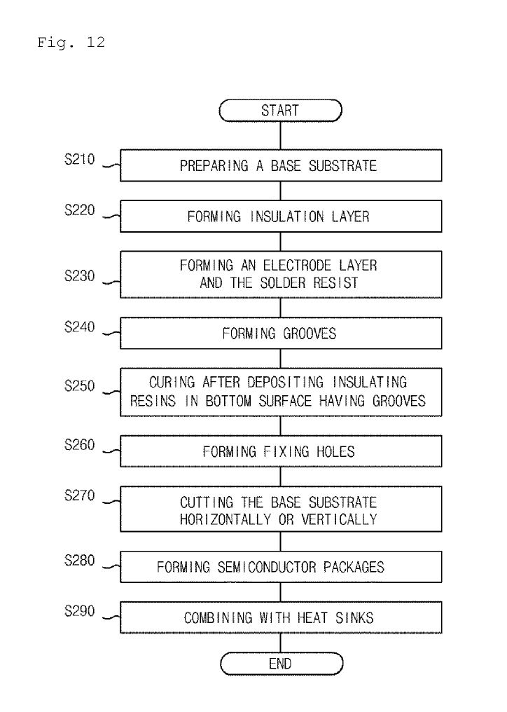

FIG. 9 is a perspective view of a base substrate for optical device manufactured according to the method described in FIG. 7. FIG. 10 is a perspective view of an optical device separated along the cutting lines in FIG. 9. FIG. 11 is a cross-sectional view of the coupled state between the optical device illustrated in FIG. 10 and the heat sink.

First, the optical device illustrated in FIG. 10, for example, may be the optical device located at the center top or center bottom with respect to the cutting line (CL) in the base substrate 100′ for optical devices illustrated in FIG. 9. In the exemplary embodiment of the present invention, an optical device of a serial-parallel structure wherein 3 optical elements are horizontally connected (serial connection) and 2 optical elements are vertically connected (parallel connection) is shown. All the horizontally and vertically arranged optical elements are disposed inside of a single cavity 150′. For the optical device illustrated in FIG. 10, the far left row and the far right row may function as a positive electrode or a negative electrode respectively.

According to an exemplary embodiment in FIG. 10, both the far left end and the far right end of the substrate become cut surfaces. Since the groove 130 is located at the bottom of the cut surfaces, generation of burrs are suppressed due to the relatively thick electrical insulation layer 140 which fills such groove 130.

Later, each of the separated optical devices are bonded to the heat sink 200 with a solder 220 through soldering process as shown in FIG. 11, and thereby the bonding between the optical device and the heat sink is completed. Owing to this bonding using soldering process, the coupling between the optical device substrate and the heat sink becomes more tight, and thereby the heat generated from the substrate may be more rapidly transferred to the heat sink.

Meanwhile, a method for manufacturing an optical device and optical devices manufactured thereby, of the present invention is not limited to the foregoing exemplary embodiment, but various changes can be made without departing from the spirit and the scope of the present invention. For example, a plating layer, for example, a silver plating layer may further be formed in the bottom surface and the peripheral surface of the cavity 140. In this case, the mask layer 185 may be removed after performing step S150. The number of the optical elements mounted on the optical device separating from the base substrates 100 and 100′ and the serial-parallel structure thereof may be properly modified.

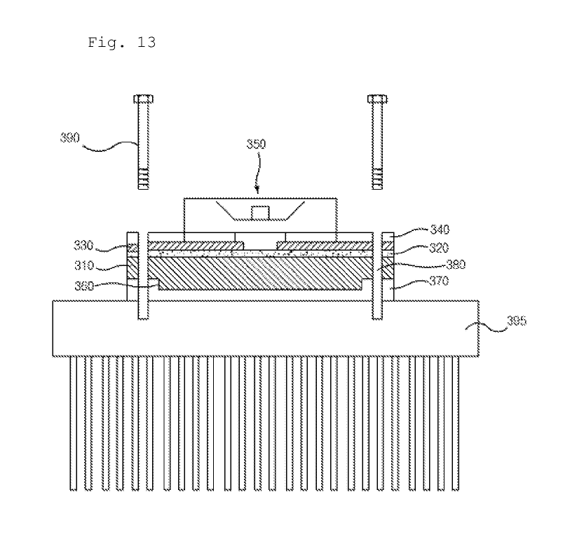

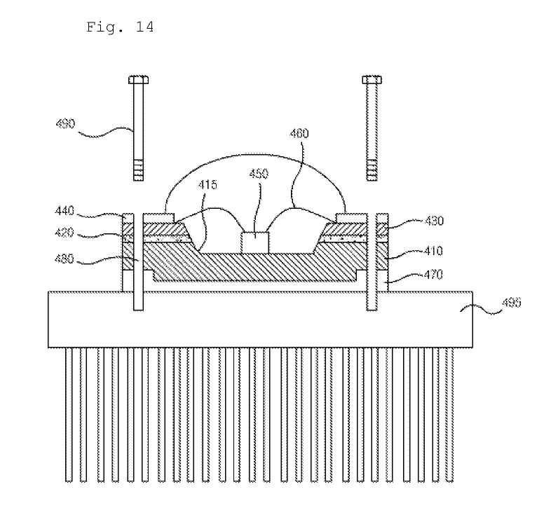

In the above exemplary embodiments a method for manufacturing an optical device having a vertical insulation layer and optical devices manufactured thereby, has been described, however, optical devices having a horizontal insulation layer may also be manufactured using a similar method without particular modifications. This will be more specifically described hereinafter. FIG. 12 is a flow diagram for describing a method for manufacturing a substrate for optical device according to another exemplary embodiment of the present invention. FIGS. 13 and 14 are exemplary cross-sectional views illustrating the coupled state between the optical device having a horizontal insulation layer, and the heat sink according to another exemplary embodiment of the present invention.

Referring to FIGS. 12 and 13, first, in step S210, a metal base substrate 300 is prepared. the metal base substrate 300 comprises a unidirectionally formed plate, and has an excellent heat conduction quality. This kind of metal base substrate 300 may be made of aluminum or aluminum alloy, and the heat transfer coefficient of aluminum or aluminum alloy is about 130 to 250 W/m²-K, which is confirmed to be high.

Next, in step S220, as illustrated in FIG. 13, a horizontal insulation layer 310 is formed on the top of the prepared metal base substrate 300. the horizontal insulation layer 310 may be formed by anodizing the upper surface of the metal base substrate 300. For reference, when the metal base substrate 300 is made of aluminum or aluminum alloy, the horizontal insulation layer 310 may be formed with aluminum oxide (Al₂O₃). In addition, the horizontal insulation layer 310 may be formed by thermal spraying of aluminum oxide (Al₂O₃) or yttrium oxide (Y₂O₃) ceramics on the top of the metal base substrate 300 using a plasma arc spray method or a cold spray method. Further, the horizontal insulation layer 310 may also be formed by mixing the anodizing and spray methods, that is, after the anodizing process is performed on the upper surface of the metal base substrate 300, then the thermal spraying may be performed on the top of it. Such a forming step of the horizontal insulation layer 310 is merely an exemplary of the invention, and it will be apparent to any person of ordinary skill in the art that it may also be formed through one of many known methods such as a diamond-like carbon (DLC) coating.

Next, in step S230, as illustrated in FIG. 13, an electrode layer 330 and an intermediate soldering layer 340 are sequentially formed on the top of the horizontal insulation layer 320, wherein a pair of the electrode layers 330 and the intermediate soldering layer 340 are formed to be spaced apart from each other. the electrode layer 330 may be formed on the top of the horizontal insulation layer 320 using any one method among arc spray method, cold spray method, paste method, ink printing method. For reference, in the ink printing method, first a fine metal component (about nano sized) such as silver or copper is prepared, and this is mixed with a dispersant and the like and provided as a uniform metal ink. Then the metal ink is sprayed on the top of the insulation layer 320, and it is cured by applying a constant heat for a predetermined time, and thereby an electrode layer 330 may be formed.

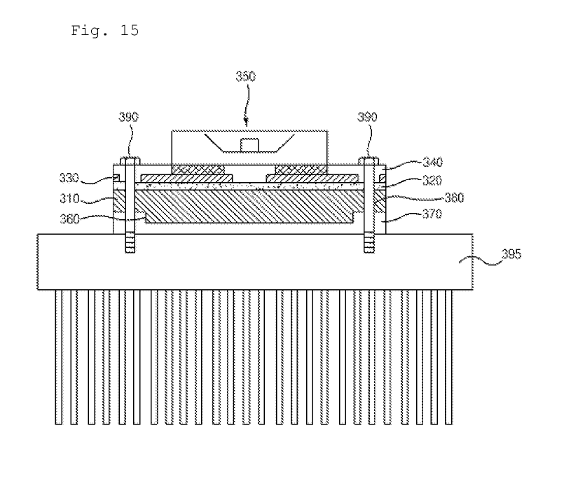

For reference, when the electrode layer 330 and the after-mentioned heat sink 395 are combined by a bolt 390, a bolt 390 made of an insulating material such as ceramic or plastic is used in order to prevent an electrical short between the electrode layer 330 and the heat sink 395. When a metal bolt is adopted instead of adopting a bolt 210 made of an insulating material due to the cost increase and the durability degradation, as illustrated in FIG. 15, an electrical short between the electrode layer 330 and the heat sink 395 caused by the metal bolt may be prevented if the electrode layer 330 is formed only up to the point which is a predetermined distance apart from the fixing hole 380.

Meanwhile, the solder resist 340 is formed to encompass the peripheral area of the electrode layer 330. the solder resist 340 insulates the peripheral area of the electrode layer 330 so as not to be externally exposed, and lets the solder 360 be formed only on the top of the exposed area of the electrode layer 330 for bonding the semiconductor chip package 350.

After the horizontal insulation layer 320, the electrode layer 330, and the solder resist 340 are sequentially formed on the metal base substrate 310, in the following step S240, a groove 130 having a sufficiently larger width than that of the cutting line (CL) is formed around the cutting line (CL) in the bottom surface of the metal base substrate as illustrated in FIG. 4B. Such groove 130 may be formed by mechanical machining or chemical etching. The depth and width of the groove 130 may be appropriately determined without affecting the hardness of the base substrate 310 and within the range such that the generation of burrs may be sufficiently prevented during the cutting process. Such groove 130 may be formed crossing the bottom surface of the base substrate 310 horizontally or vertically depending on the overall size of the base substrate 310 or the number of optical devices to be arranged in the base substrate 310.

Next, in step S250, as illustrated in FIG. 4C, in the bottom surface of the base substrate 310 wherein a groove 130 is formed, the groove 360 is filled with a liquid heat dissipating epoxy until the overall surface is flattened thereby, then an electrical insulation layer 370 is formed by curing the liquid heat dissipating epoxy while heating. The material of such heat dissipating epoxy may be a thermo-plastic or a thermosetting epoxy resin, and the like.

An integral TIM is formed in the bottom surface of the metal base substrate 310 as an electrical insulation layer 370. Next, in step S260, a plurality of fixing holes 380, which penetrate all of the metal base substrate 310, the horizontal insulation layer 320, the electrode layer 330, and the solder resist 340, are formed. The locations or the number of the fixing holes 380 may be appropriately determined according to the number of the optical devices to be separated or the structure of the wire connection thereof.

Next, in step S270, the metal base substrate is separated by cutting (hereinafter each of the separated metal base substrate shall be referred to as ‘metal substrate 310’) in either horizontally or vertically along the cutting line (CL) drawn in dotted lines in the metal base substrate 410 as illustrated in FIG. 4C. As illustrated in FIG. 13, a semiconductor package is formed (step S280) on the electrode layer 330 formed on the top of each metal substrate 310 which has been cut and separated, then combined (step S290) with the heat sink 395 using a fixing bolt 390. As described above, a bolt made of an insulating material may be used as a fixing bolt 390, and a metal bolt may also be used by isolating the electrode layer 330 from the periphery of the fixing hole 380.

A cross-sectional view of an optical device manufactured by the exemplary method in FIG. 12 is shown in FIG. 13 as an example. Referring to an optical device illustrated in FIG. 13, according to a method for manufacturing optical devices: the heat dissipating characteristics may be enhanced by bonding a heat dissipating epoxy layer, which can be formed to have a relatively thinner thickness than the adhesive TIM layer of the prior art, to the bottom surface of the substrate 310; generation of metallic burrs during the cutting process of the substrate 310 is suppressed by forming a groove around the cutting area and depositing a heat dissipating epoxy layer into the groove and curing it thereafter; and it is effective in reducing the possibility of electrical short through enhancement of the electrical insulation since the periphery (of the burrs) is encompassed by the heat dissipating epoxy layer even when the burrs are generated.

In addition, not only the bonding between the heat sink and the substrate can be easily performed by integrating the electrical insulation layer, which is used as a TIM, into the substrate, but also the uniform heat dissipating characteristics can be guaranteed independent of workmanship of the workers.

FIG. 14 is another exemplary embodiment of the present invention, and shows an exemplary cross-sectional view illustrating the coupled state between the optical device, which is manufactured by the method for manufacturing optical device having a horizontal insulation layer, and the heat sink, and this device may also be manufactured through the similar manufacturing process illustrated in FIG. 12. This will be described in detail hereinafter.

As a first step, a metal base substrate 410 is prepared as shown in FIG. 12. the metal base substrate 410 may be made of aluminum or aluminum alloy. As a second step, a horizontal insulation layer 420 is formed on the top of the prepared metal base substrate 410. the horizontal insulation layer 420 may be formed either by anodizing the top surface of the metal base substrate 300 or coating ceramics using at least any one selected from plasma arc spray method or cold spray method. Later, an electrode layer 430 is formed on the top of the horizontal insulation layer 420 using plasma arc spray method, cold spray method, or paste method, then a solder resist 440 is formed to encompass the periphery of the electrode layer 430.

After the horizontal insulation layer 420, the electrode layer 430, and the solder resist 440 are sequentially formed on the metal base substrate 410, a groove 130 having a sufficiently larger width than that of the cutting line (CL) is formed around the cutting line (CL) in the bottom surface of the metal base substrate as illustrated in FIG. 4B. Such groove 130 may be formed by mechanical machining or chemical etching. The depth and width of the groove 130 may be appropriately determined without affecting the hardness of the base substrate and within the range such that the generation of burrs may be sufficiently prevented during the cutting process.

Next, as illustrated in FIG. 4C, in the bottom surface of the base substrate wherein a groove 130 is formed, the groove 130 is filled with a liquid heat dissipating epoxy until the overall surface is flattened thereby, then an electrical insulation layer 470, as a TIM, is formed by curing the liquid heat dissipating epoxy while heating. The material of such heat dissipating epoxy may be a thermo-plastic or a thermosetting epoxy resin, and the like.

Again referring to FIG. 14, an integral TIM is formed in the bottom surface of the metal base substrate 410 as an electrical insulation layer 470, then a plurality of fixing holes 480, which penetrate all of the metal base substrate 410, the horizontal insulation layer 420, the electrode layer 430, and the solder resist 440, are formed. The locations or the number of the fixing holes 480 may be appropriately determined according to the number of the optical devices to be separated or the structure of the wire connection thereof.

Meanwhile, a substrate pattern forming step for forming the groove 415 in the base substrate 410 is performed by mechanically machining the metal base substrate 410, wherein the horizontal insulation layer 420 and the electrode layer 430 is formed, from the top. Mechanical machining may be performed using a typical CNC milling machine or through a milling process known to the public. Such substrate pattern forming step may be performed prior to machining of the groove. When a groove 415 is formed on the top of the base substrate 410 after performing the substrate pattern forming step, an optical element 450 is bonded on the top of the base substrate 410 using an adhesive. In addition, after connecting the electrode layer 430 and the optical element 450 using a conductive wire 460 which can be made of gold, copper, or aluminum, a paste containing fluorescent substance is applied for protecting the optical element 450 and the like from the external impact, and the light generated from the optical element 450 can be converted into a white light. Later, the metal base substrate is separated by cutting (hereinafter each of the separated metal base substrate shall be referred to as ‘metal substrate 310’) in either horizontally or vertically along the cutting line (CL) drawn in dotted lines in the metal base substrate 410 as illustrated in FIG. 4C, and subsequently combined with the heat sink 495 using a fixing bolt 490. In this exemplary embodiment, a bolt made of an insulating material may be used as a fixing bolt 490, and a metal bolt may also be used by isolating the electrode layer 430 from the periphery of the fixing hole 480.

Referring to an optical device manufactured according to such method, as previously mentioned: the heat dissipating characteristics may be enhanced by bonding a heat dissipating epoxy layer, which can be formed to have a relatively thinner thickness than the adhesive TIM layer of the prior art, to the bottom surface of the substrate 410; generation of metallic burrs during the cutting process of the substrate 310 is suppressed by forming a groove around the cutting area and depositing a heat dissipating epoxy layer into the groove and curing it thereafter; and it is effective in reducing the possibility of electrical short through enhancement of the electrical insulation since the periphery (of the burrs) is encompassed by the heat dissipating epoxy layer even when the burrs are generated.

In addition, not only the bonding between the heat sink and the substrate can be easily performed by integrating the electrical insulation layer, which is used as a TIM, into the substrate, but also the uniform heat dissipating characteristics can be guaranteed independent of workmanship of the workers.

Although an exemplary optical device having two types of horizontal insulation layer is described to be manufactured according to a predetermined sequence, it may also be manufactured with a modified sequence as necessary. For example, although it is described that after forming the horizontal insulation layer, the electrode layer, and the solder resist in the metal base substrate, a groove is formed in the bottom surface of the metal base substrate, followed by the remaining processes; instead, a groove may be formed in the bottom surface of the metal base substrate prior to forming of the horizontal insulation layer, the electrode layer, and the solder resist; then the groove is filled with a heat dissipating epoxy layer is deposited and cured; thereafter, the horizontal insulation layer and the electrode layer may be formed.

Further, in the exemplary embodiments of the present invention, it is described that a liquid heat dissipating epoxy is deposited over the fully filled (with the epoxy) groove in the bottom surface of the base substrate wherein the groove is formed, for surface flattening. However, since such integral TIM is made of epoxy component, all the internal space of the groove may not completely filled according to the expansion of the metal substrate and the volume contraction of the epoxy due to the temperature increase during the curing process. In order to solve this problem, after filling the inside of the groove using an epoxy mixed with ceramic component powder such as alumina to reduce the volume contraction during the curing process, only epoxy may be deposited for flattening of the bottom surface of the base substrate. In this case, an additional effect may be obtained that the heat transfer coefficient of the integral TIM may be relatively improved due to the ceramic component powder.

In addition, in the exemplary embodiment of the present invention, it is described that the heat sink and the substrate which is combined with an integral TIM are bonded together using a bolt, however, a TIM having adhesive force may be combined with the heat sink without using a bolt. That is, the heat sink may be bonded at the bottom end of an electrical insulation layer having an adhesive force by forming an electrical insulation layer (TIM), which is a component of the present invention, using any one from silicon resins, acrylic resins, urethane resins, or a combination of these resins.

As described above, although the present invention is described with reference to the exemplary embodiments illustrated in the drawings, this is merely an example, a person of ordinary skill in the art will understand that various modifications and other equivalent exemplary embodiments are possible therefrom. Thus, true technical protection range of the present invention must be determined as defined in the appended claims and their equivalents.

### Explanation of Reference Numerals

10: TIM layer

20: heat sink

22: insulation layer

30: substrate

32: vertical insulation layer

34: cavity

40: optical element

42: wire

100, 100′: base substrate

110: vertical insulation layer

120: optical device substrate

130: groove,

140: electrical insulation layer

150, 150′: cavity

160: fixing hole

170: optical element,

175, 175′: wire

180: seed layer

185: mask layer

190: plating layer

200: heat sink

210: fixing bolt

220: solder layer

CL: cutting line.

1. An optical device manufactured by a process comprising:
(a) preparing a base substrate for optical device having a vertical insulation layer;
(b) forming a groove along a cutting line in a bottom surface of the base substrate;
(c) forming an electrical insulation layer having a flat surface by applying and curing a liquid insulation material on a surface where the groove is formed; and
(d) forming a fixing hole vertically penetrating both the base substrate and the groove.

2. The optical device according to claim 1, wherein a cavity having a groove having a predetermined depth starting from an upper surface of the base substrate and accommodating the vertical insulation layer is formed after the step (c) and before, simultaneously with or after the step (d).

3. The optical device according to claim 1, wherein the process further comprises:
(e) bonding a wire after an optical element is mounted on an upper surface of the base substrate.

4. The optical device according to claim 3, wherein the process further comprises:
(f) separating the optical device manufactured through the step (e) along the cutting line.

5. The optical device according to claim 2, wherein the process further comprises:
(e-1) bonding a wire after the optical element is disposed in the cavity of the base substrate.

6. The optical device according to claim 5, the process further comprises:
(f-1) separating the optical device manufactured through the step (e-1) along the cutting line.

7-19. (canceled)

20. A method for manufacturing an optical device comprising:
(a) preparing a base substrate for optical device having a vertical insulation layer;
(b) forming a groove along a cutting line in a bottom surface of the base substrate;
(c) forming an electrical insulation layer having a flat surface by applying and curing a liquid insulation material on a surface where the groove is formed; and
(d) forming a fixing hole vertically penetrating both the base substrate and the groove.

21. An optical device manufactured by a process comprising:
(h) preparing a base substrate for optical device having a vertical insulation layer;
(i) forming a groove on a bottom surface of the base substrate along a cutting line;
(j) forming an electrical insulation layer having a flat surface by curing a liquid insulation material applied over a surface where the groove is formed; and
(k) forming an intermediate soldering layer on the electrical insulation layer.

22. The optical device according to claim 21, wherein the step (k) comprises:
(k-1) forming a seed layer using a sputtering process or an activation treatment process for palladium (Pd) on the electrical insulation layer; and
(k-2) forming a plating layer using an electroplating process or an electroless plating process on the seed layer.

23. The optical device according to claim 22, wherein the step (k-1) is performed in a state where a masking layer is formed on an upper surface of the base substrates, and
the step (k-2) is performed after a cavity having a groove having a predetermined depth starting from the upper surface of the base substrate and accommodating the vertical insulation layer is formed after the step (k-1).

24. The optical device according to claim 22, wherein the process further comprises:
(l) wire-bonding an optical element after the optical element is mounted on an upper surface of the base substrate; and
(m) separating the optical device along the cutting line.

25. The optical device according to claim 24, wherein the process further comprises:
(n) wire-bonding the optical element after the optical element is disposed in the cavity of the base substrate; and
(o) separating the optical device along the cutting line.

26. The optical device according to claim 21, wherein the liquid insulation material being used in the forming step of the electrical insulation layer is classified into a first liquid insulation material and a second insulation material, wherein the first liquid insulation material is an epoxy resin mixed with ceramic powder and is filled into an inside of the groove, and the second insulation material is either a thermo-plastic or a thermosetting epoxy resin and is deposited and cured on the bottom surface of the base substrate.

27. A method for manufacturing an optical device comprising:
(h) preparing a base substrate for optical device having a vertical insulation layer;
(i) forming a groove on a bottom surface of the base substrate along a cutting line;
(j) forming an electrical insulation layer having a flat surface by curing a liquid insulation material applied over a surface where the groove is formed; and
(k) forming an intermediate soldering layer on the electrical insulation layer.

28. An optical device, wherein a horizontal insulation layer and an electrode layer are formed on a top of a metal substrate, and the electrode layer is electrically connected with either an optical element or an optical element package, the optical device manufactured by a process comprising:
forming a groove on a bottom surface of the metal substrate along a cutting line;
forming an electrical insulation layer having a flat surface by curing a liquid insulation material applied over the surface where the groove is formed; and
forming a fixing hole which vertically penetrates the groove, a metal substrate located on a center axis of the groove and stacked members on a top surface of the metal substrate so as to be combined with a heat sink.

29. The optical device according to claim 28, wherein the process further comprises:
separating the optical device manufactured through the foregoing steps along the cutting line.

30. The optical device according to claim 29, wherein the electrical insulation layer is a liquid insulating material containing more than any one of aluminum oxide, zinc oxide and boron nitride having a high heat transfer coefficient.

31. A method for manufacturing an optical device, wherein a horizontal insulation layer and an electrode layer are formed on a top of a metal substrate, and the electrode layer is electrically connected with either an optical element or an optical element package, the method comprising:
forming a groove on a bottom surface of the metal substrate along a cutting line;
forming an electrical insulation layer having a flat surface by curing a liquid insulation material applied over the surface where the groove is formed; and
forming a fixing hole which vertically penetrates the groove, a metal substrate located on a center axis of the groove and stacked members on a top surface of the metal substrate so as to be combined with a heat sink.

32. An optical device, wherein a horizontal insulation layer and an electrode layer are formed on a top of a metal substrate, and the electrode layer is electrically connected with either an optical element or an optical element package, the optical device manufactured by a process comprising:
forming a groove on a bottom surface of the metal substrate along a cutting line;
forming an electrical insulation layer having a flat surface by curing a liquid insulation material which has an adhesive strength and applied over a surface where the groove is formed; and
bonding a heat sink to a bottom end of the electrical insulation layer having adhesive strength.

33. A method for manufacturing an optical device, wherein a horizontal insulation layer and an electrode layer are formed on a top of a metal substrate, and the electrode layer is electrically connected with either an optical element or an optical element package, the method comprising:
forming a groove on a bottom surface of the metal substrate along a cutting line;
forming an electrical insulation layer having a flat surface by curing a liquid insulation material which has an adhesive strength and applied over a surface where the groove is formed; and
bonding a heat sink to a bottom end of the electrical insulation layer having adhesive strength.

34. An optical device comprising:
a base substrate having a vertical insulation layer;
an insulation layer having a flat surface formed by applying and curing a liquid insulation material on a surface where a groove is formed along a cutting line in a bottom surface of the base substrate; and
a fixing hole vertically penetrating both the base substrate and the groove.

35. An optical device comprising:
a base substrate having a vertical insulation layer; and
an electrical insulation layer having a flat surface formed by applying and curing a liquid insulation material on a surface where a groove is formed along a cutting line in a bottom surface of the base substrate; and
an intermediate soldering layer formed on the electrical insulation layer.
